(19) United States
(12) Patent Application Publication
(10) Pub. No.: US 2012/0325538 A1
(43) Pub. Date: Dec. 27, 2012

(54) PRINTED CIRCUIT BOARD ASSEMBLY

(75) Inventor: Peter Chiang, New Taipei City (TW)

(73) Assignee: MICRO-STAR INTERNATIONAL COMPANY LIMITED, New Taipei City (TW)

(21) Appl. No.: 13/606,164

(22) Filed: Sep. 7, 2012

Related U.S. Application Data
(63) Continuation-in-part of application No. 12/228,706, filed on Aug. 15, 2008.

(30) Foreign Application Priority Data
Feb. 27, 2008 (TW) 097106827

(51) Int. Cl. H05K 1/18

(52) U.S. Cl. 174/260

(57) ABSTRACT

A printed circuit board assembly includes: a base material of printed boards; a solder pad formed on a pad-forming portion of the base material of printed boards and having a lead-coupling portion, a soldermask-covered portion, and an intermediate portion interposed therebetween; a soldermask having a solder pad-covering portion formed on the soldermask-covered portion of the solder pad and a remainder portion formed on the base material of printed boards; and a solder paste having one portion formed on the lead-coupling portion of the solder pad and attached to a lead of an electronic component, and the other portion formed on the intermediate portion of the solder pad, the solder pad-covering portion of the soldermask being substantially free of solder paste thereabove.

### CROSS-REFERENCE TO RELATED APPLICATION

This application is a continuation-in-part of U.S. patent application Ser. No. 12/228,706 (hereinafter referred to as the '706 application). The '706 application, entitled “Printed Circuit Board Assembly,” was filed on Aug. 15, 2008 and claims priority of Taiwanese application no. 097106827, filed on Feb. 27, 2008.

### BACKGROUND OF THE INVENTION

1. Field of the Invention

This invention relates to a printed circuit board assembly, more particularly to a printed circuit board assembly including a solder pad covered by a portion of a soldermask, the portion of the soldermask being substantially free of any solder paste thereabove.

2. Description of the Related Art

Electronic components can be classified into two types: plated through-hole components and surface mount components. The plated through-hole components usually have pins for extending respectively into holes in a printed circuit board so that the pins are soldered to a back side of the printed circuit board after passing through a solder oven. The surface mount components have end caps for mounting directly on a surface of a printed circuit board.

FIG. 1 illustrates a conventional printed circuit board 9 including a substrate 93, a soldermask 94 formed on the substrate 93 and formed with a recess 941, a pair of solder pads 92, which are received in the recess 941 and separated from the soldermask 94, a pair of conductive traces 95 each extending from a respective one of the solder pads 92 and each having a first end portion 951 covered by the soldermask 94 and a second end portion 952 that extends between the first end portion 951 of the conductive trace 95 and the respective solder pad 92, and that is exposed to the atmosphere, and a lead-free solder paste 91 applied on the solder pads 92 for connecting leads 961 of an electronic component 96 thereto.

During soldering, the leads 961 of the electronic component 96 are attached to the lead-free solder paste 91 on the solder pads 92 of the printed circuit board 9, and the assembly is subsequently disposed in a reflow-soldering oven so as to conduct soldering. Since the lead-free solder paste 91 has a high surface tension, the lead-free solder paste 91 contracts so as to minimize the surface area thereof, which results in undesired exposure of a portion of each of the solder pads 92 to the atmosphere after soldering, which, in turn, results in problems, such as open-circuit in the solder joint, naked copper, cold joint, and generation of ineffective soldering area for the solder pads 92. In addition, the joint area between each solder pad 92 and the respective conductive trace 95 tends to corrode after a period of use.

Taiwanese Patent No. 249213 discloses a printed circuit board including a pair of solder pads formed on a substrate, a soldermask formed on the substrate and a portion of each solder pad, and a lead-free solder paste applied on the remainder of each solder pad by screen printing techniques. However, the problems of generation of ineffective soldering area and cold joint are still present.

FIGS. 3B and 3C of U.S. Pat. No. 6,396,707, Huang et al. disclose a conventional ball grid array package, which is not a printed circuit board per se, but is adapted to be mounted on a printed circuit board. Referring to the description in lines 51-62, column 2 of the Specification of this U.S. patent, the soldermask covers up to the peripheral portion of the ball pad leaving only a center portion of the ball pad exposed by the ball pad opening. The anchor force of the soldermask covering the peripheral portion of the solder pads can strengthen the solder joint between the solder pads and the substrate. Thus, in the ball grid array package of FIG. 3B of this U.S. patent, the entire peripheral portion of the solder pads is covered by the soldermask so as to define the central ball pad openings for receiving the solder balls (not a solder paste) and the peripheries of the openings tend to be covered by the solder balls.

U.S. Pat. No. 6,521,997 B1 to Huang et al. discloses a chip carrier for accommodating a passive component that may be mounted on a printed circuit board. The chip carrier is not a printed circuit board per se. Referring to FIGS. 1 and 3 and the accompanying description in lines 5-40, column 3 of the Specification of this U.S. patent, the chip carrier has a structure similar to that of the ball grid array package of FIG. 3B of U.S. Pat. No. 6,396,707, i.e., the entire peripheral portion of the solder pad is covered by the soldermask so as to define a central opening and a solder paste is formed in the central opening and on the peripheral portion of the solder pad through the soldermask. During reflowing, the solder paste tends to randomly flow over the soldermask.

### SUMMARY OF THE INVENTION

Therefore, one object of the present invention is to provide a printed circuit board assembly that can overcome the aforesaid drawbacks associated with the prior art.

According to the present invention, a printed circuit board assembly includes: a base material of printed boards having a pad-forming portion; a solder pad formed on the pad-forming portion of the base material of printed boards and having a lead-coupling portion, a soldermask-covered portion and an intermediate portion interposed between the lead-coupling portion and the soldermask-covered portion; a soldermask having a solder pad-covering portion formed on the soldermask-covered portion of the solder pad and a remainder portion formed on the base material of printed boards, the remainder portion of the soldermask being formed with a recess to expose the pad-forming portion of the base material of printed boards formed with the intermediate portion and the lead-coupling portion of the solder pad; an electronic component disposed above the solder pad and having a lead attached to the lead-coupling portion of the solder pad; and a solder paste having one portion formed on the lead-coupling portion of the solder pad and attached to the lead of the electronic component such that the lead is electrically coupled to the lead-coupling portion of the solder pad, and the other portion formed on and substantially entirely covering the intermediate portion of the solder pad and being laterally in contact with the lead of the electronic component, the solder pad-covering portion of the soldermask being substantially free of solder paste thereabove.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a perspective view of a conventional printed circuit board;

FIG. 2 is a perspective view of the first preferred embodiment of a printed circuit board assembly according to this invention before reflowing and being mounted with an electronic component;

FIG. 3 is a perspective view of the second preferred embodiment of a printed circuit board assembly according to this invention before reflowing and being mounted with an electronic component;

FIGS. 4 to 7 are perspective views to illustrate consecutive steps of a method for making the printed circuit board assembly according to this invention; and

FIGS. 8 to 11 are fragmentary sectional views of FIGS. 4 to 7, respectively.

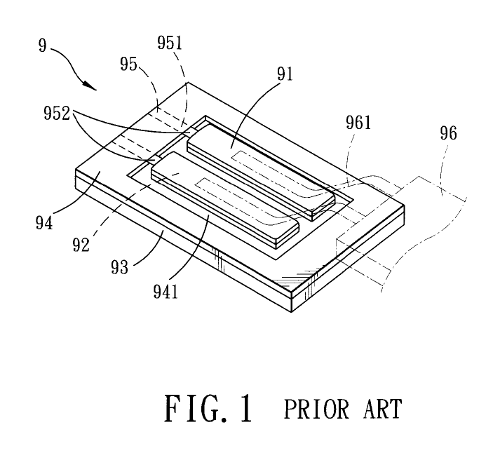

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

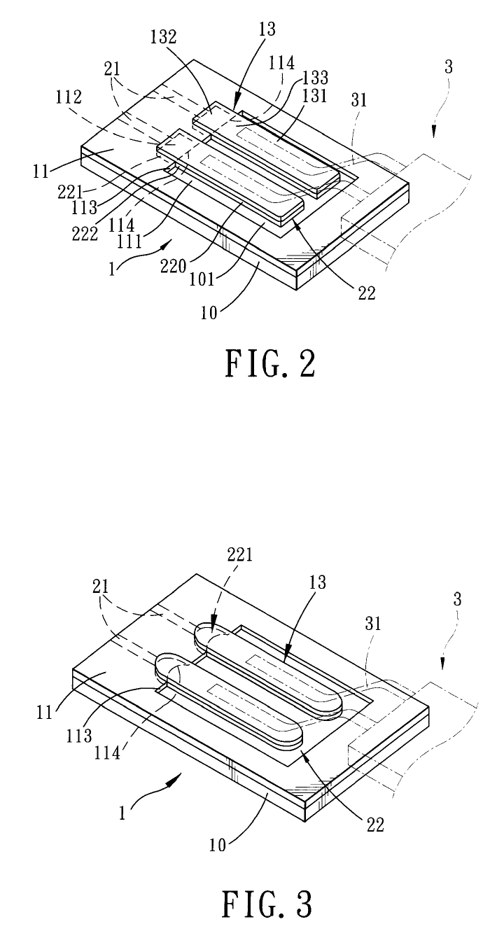

FIG. 2 illustrates the first preferred embodiment of a printed circuit board assembly 1 according to this invention before reflowing and being mounted with an electronic component. The printed circuit board assembly 1 includes a base material of printed boards 10, a pair of solder pads 22, a soldermask 11, and a lead-free solder paste 13.

The soldermask 11 is formed on the base material of printed boards 10 and formed with a recess 111 so as to expose a pad-forming portion 101 of the base material of printed boards 10.

Each of the pair of solder pads 22 has a lead-coupling portion 220, a soldermask-covered portion 221, and an intermediate portion 222 interposed between the lead-coupling portion 220 and the soldermask-covered portion 221. The lead-coupling portion 220 and the intermediate portion 222 of each solder pad 22 are received in the recess 111 of the soldermask 11 and formed on the pad-forming portion 101 of the base material of printed boards 10.

The soldermask 11 has a solder pad-covering portion 112 formed on the soldermask-covered portion 221 of each solder pad 22 and a remainder portion formed on the base material of printed boards 10. The remainder portion of the soldermask 11 is formed with the recess 111 from which the intermediate portion 222 and the lead-coupling portion 221 of each solder pad 22 formed on the pad-forming portion 101 of the base material of printed boards 10 are exposed.

The lead-free solder paste 13 has a first end portion 131 formed on the lead-coupling portion 220 of each of the solder pads 22, a second end portion 132 formed on the solder pad-covering portion 112 of the soldermask 11, and an intermediate portion 133 interposed between the first and second end portions 131, 132 and covering the intermediate portion 222 of each of the solder pads 22.

In this embodiment, the printed circuit board assembly 1 further includes a pair of conductive traces 21 each of which is formed on the base material of printed boards 10, covered by the soldermask 11, and connected to the soldermask-covered portion 221 of a respective one of the solder pads 22.

In this embodiment, the recess 111 of the soldermask 11 has a peripheral edge 113, which has a segment 114 dividing each of the solder pads 22 into the lead-coupling and intermediate portions 220, 222 that are exposed from the recess 111 and the soldermask-covered portion 221. The segment 114 is linear in shape.

Preferably, the lead-coupling and soldermask-covered portions 220, 221 of each of the solder pads 22 are opposite to each other in a direction along the length of the solder pad 22.

The soldermask-covered portion 221 of each of the solder pads 22 has a length along the direction ranging from 4 to 6 mil.

Preferably, each of the conductive traces 21 and the solder pads 22 is made from copper.

FIG. 3 illustrates the second preferred embodiment of the printed circuit board assembly 1 according to the present invention before reflowing. The second preferred embodiment differs from the previous embodiment in that the segment 114 is curved in shape.

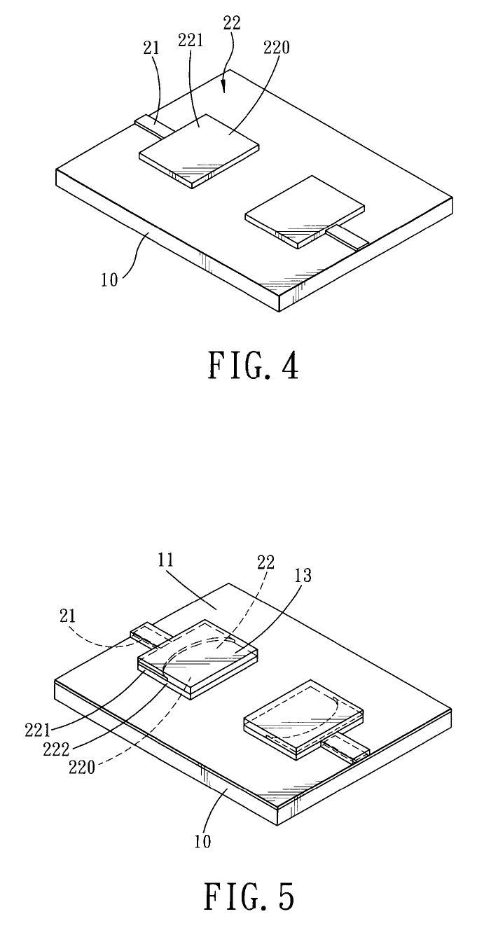

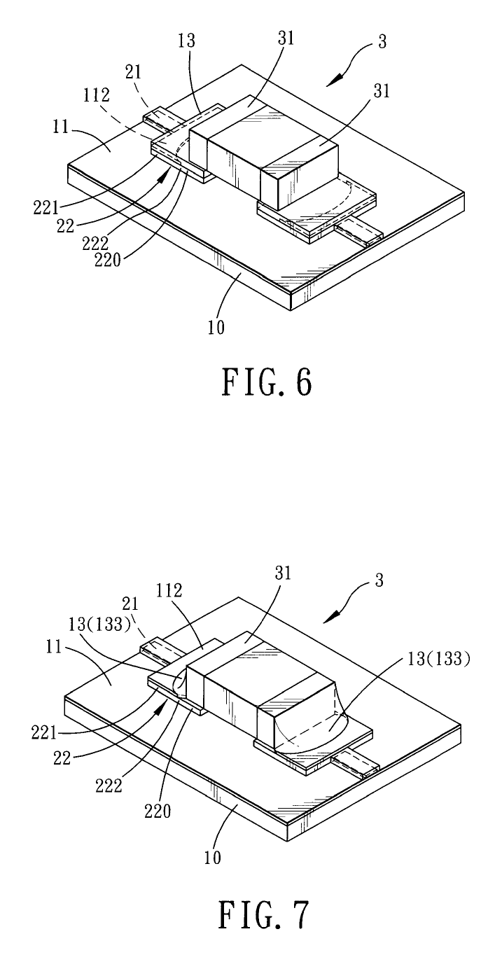

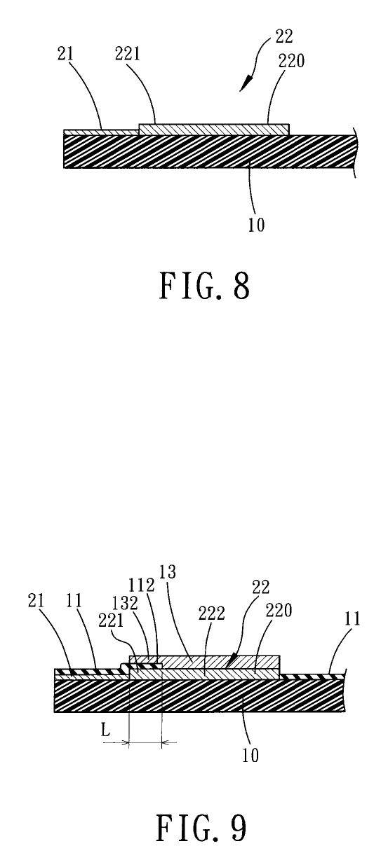

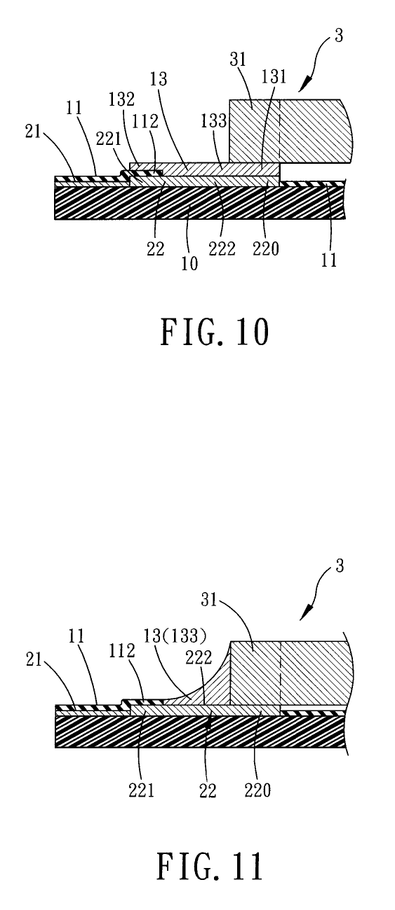

This invention also provides a method for making the printed circuit board assembly 1 with at least one electronic component 3 soldered thereto. The method includes: (a) forming the solder pads 22 on the base material of printed boards 10 (see FIGS. 4 and 8); (b) covering the base material of printed boards 10 and the soldermask-covered portion 221 of each of the solder pads 22 using the soldermask 11 (see FIGS. 5 and 9); (c) applying the lead-free solder paste 13 on the solder pad-covering portion 112 of the soldermask 11 (see FIGS. 5 and 9), which is formed on the soldermask-covered portion 221 of each of the solder pads 22, and on the remainder, i.e., the lead-coupling and intermediate portions 220, 222 of the solder pads 22; (d) attaching leads 31 of the electronic component 3 to the lead-free solder paste 13 (see FIGS. 6 and 10); and (e) reflowing the lead-free solder paste 13 on the solder pads 22 (see FIGS. 7 and 11).

Referring to FIG. 11, the printed circuit board assembly 1 with at least one electronic component 3 fabricated by the above-mentioned method is shown. In the printed circuit board assembly 1 thus formed, the intermediate portion 133 of the lead-free solder paste 13 is formed on and substantially entirely covers the intermediate portion 222 of the solder pad 22 and is laterally in contact with the lead 31 of the electronic component 3, the solder pad-covering portion 112 of the soldermask 11 being substantially free of solder paste thereabove.

Preferably, the method further includes forming the conductive traces 21 on the base material of printed boards 10, each of which is connected to the soldermask-covered portion 221 of the respective solder pad 22 and is covered by the soldermask 11.

Particularly, referring to FIGS. 10 and 11, during reflowing of the lead-free solder paste 13, because of surface tension of the lead-free solder paste 13, the second end portion 132 of the lead-free solder paste 13 tends to contract toward the leads 31 of the electronic component 3 and aggregate to the intermediate portion 133 of the lead-free solder paste 13 and the first end portion 131 of the lead-free solder paste 13 likewise tends to contract toward and aggregate to the intermediate portion 133 of the lead-free solder paste 13. Hence, since the second end portion 132 of the lead-free solder paste 13 formed on the solder pad-covering portion 112 of the soldermask 11 is able to compensate for loss of the intermediate portion 133 of the lead-free solder paste 13 during reflowing, the intermediate portion 133 of the lead-free solder paste 13 after reflowing is able to entirely cover the intermediate portion 222 of each of the solder pads 22 exposed from the recess 111 of the soldermask 11, to be laterally in contact with the leads 31 of the electronic component 3 and to completely cover the lead-coupling portion 220 of each of the solder pads 22, and the effective volume of the lead-free solder paste 13 for soldering the leads 31 of the electronic component 3 can be increased. Consequently, the aforesaid drawbacks associated with the prior art, such as generation of the ineffective solder area or occurrence of naked copper and cold joint for the solder pads 22, can be avoided.

With the invention thus explained, it is apparent that various modifications and variations can be made without departing from the spirit of the present invention. It is therefore intended that the invention be limited only as recited in the appended claims.

What is claimed is:

1. A printed circuit board assembly comprising:
a base material of printed boards having a pad-forming portion;
a solder pad formed on said pad-forming portion of said base material of printed boards and having a lead-coupling portion, a soldermask-covered portion and an intermediate portion interposed between said lead-coupling portion and said soldermask-covered portion;
a soldermask having a solder pad-covering portion formed on said soldermask-covered portion of said solder pad and a remainder portion formed on said base material of printed boards, said remainder portion of said soldermask being formed with a recess to expose said pad-forming portion of said base material of printed boards formed with said intermediate portion and said lead-coupling portion of said solder pad;
an electronic component disposed above said solder pad and having a lead attached to said lead-coupling portion of said solder pad; and
a solder paste having one portion formed on said lead-coupling portion of said solder pad and attached to said lead of said electronic component such that said lead is electrically coupled to said lead-coupling portion of said solder pad, and the other portion formed on and substantially entirely covering said intermediate portion of said solder pad and being laterally in contact with said lead of said electronic component, said solder pad-covering portion of said soldermask being substantially free of solder paste thereabove.

2. The printed circuit board assembly of claim 1, further comprising a conductive trace formed on said base material of printed boards, covered by said soldermask, and connected to said soldermask-covered portion of said solder pad.

3. The printed circuit board assembly 1 of claim 1, wherein said recess of said soldermask has a peripheral edge, which has a segment dividing said solder pad into said lead-coupling and intermediate portions that are exposed from said recess and said soldermask-covered portion, said segment being linear in shape.

4. The printed circuit board assembly of claim 1, wherein said recess of said soldermask has a peripheral edge, which has a segment dividing said solder pad into said lead-coupling and intermediate portions that are exposed from said recess and said soldermask-covered portion, said segment being curved in shape.

5. The printed circuit board assembly of claim 1, wherein said lead-coupling and soldermask-covered portions of said solder pad are opposite to each other in a direction along the length of said solder pad, said soldermask-covered portion of said solder pad covered by said solder pad-covering portion of said soldermask having a length along the direction ranging from 4 to 6 mil.
